(19) United States
(12) Patent Application Publication
(10) Pub. No.: US 2023/0295790 A1
(43) Pub. Date: Sep. 21, 2023

(54) Full Mask Sheet, Mask Sheet Assembly and Evaporation Device

(71) Applicants: Chengdu BOE Optoelectronics Technology Co., Ltd., Chengdu, Sichuan (CN); BOE Technology Group Co., Ltd., Beijing (CN)

(72) Inventors: Yan HUANG, Beijing (CN); Jianpeng WU, Beijing (CN); Qian XU, Beijing (CN); Tong NIU, Beijing (CN); Guomeng ZHANG, Beijing (CN)

(21) Appl. No.: 17/610,157

(22) PCT Filed: Jan. 22, 2021
(86) PCT No.: PCT/CN2021/073312

§ 371 Date: Nov. 10, 2021

(51) Int. Cl. C23C 14/04; C23C 14/24; H10K 71/16

(52) U.S. Cl. CPC C23C 14/042; C23C 14/24; H10K 71/166

(57) ABSTRACT

A full mask sheet, a mask sheet assembly and an evaporation device are provided. The full mask sheet includes a sheet body including a first surface which is configured to support multiple fine metal mask sheets of the mask sheet assembly, and the sheet body is provided with multiple openings which are configured to expose mask pattern regions of the fine metal mask sheets. The sheet body includes a first region near a circumferential edge and a second region surrounded by the first region, and a first surface of the second region protrudes from a first surface of the first region in a direction perpendicular to the sheet body. The first surface of the first region is provided with a support portion which avoids the opening, and the support portion is configured to support the multiple fine metal mask sheets together with the first surface of the second region.

### CROSS-REFERENCE TO RELATED APPLICATION

The present application is a U.S. National Phase Entry of International Application PCT/CN2021/073312 having an international filing date of Jan. 22, 2021 and entitled “Full Mask Sheet, Mask Sheet Assembly and Evaporation Device”, the contents of which should be construed as being hereby incorporated by reference in their entirety.

### TECHNICAL FIELD

Embodiments of the present disclosure relate to, but are not limited to, the field of display technology, in particular to a full mask sheet, a mask sheet assembly and an evaporation device.

### BACKGROUND

In a manufacturing technology of an organic light-emitting diode (OLED) display panel, organic film layers such as light-emitting layers of OLED devices are mainly manufactured by vacuum evaporation process. A mask sheet assembly used in the vacuum evaporation process is mainly composed of a frame, a full mask sheet and a fine metal mask sheet (FMM), wherein the full mask sheet and multiple fine metal mask sheets are all welded on the frame, the full mask sheet is mainly used for supporting the fine metal mask sheets and defining an evaporation region of a base substrate, and the fine metal mask sheets are supported on the full mask sheet. In an evaporation process, the base substrate is attached to the fine metal mask sheets, and an evaporation material in an evaporation source is heated to form vapor, which is deposited in a preset region of the base substrate through a mask pattern region of the fine metal mask sheet, thereby forming a film layer with a corresponding pattern on the base substrate.

In some technologies, a magnetic adsorption device is disposed in an evaporation chamber, and the mask sheet assembly is subjected to a magnetic adsorption action of the magnetic adsorption device, so that the fine metal mask sheets and the base substrate are closely attached to ensure that the evaporation material is accurately evaporated to the preset region of the base substrate. However, during the evaporation process, the fine metal mask sheets are prone to wrinkle, which leads to poor evaporation accuracy and causes defects such as color mixing.

### SUMMARY

The following is a summary of the subject matters described in the present disclosure in detail. The summary is not intended to limit the scope of protection of the claims.

An embodiment of the present disclosure provides a full mask sheet of a mask sheet assembly, wherein the full mask sheet includes a sheet body including a first surface, wherein the first surface of the sheet body is configured to support multiple fine metal mask sheets of the mask sheet assembly, and the sheet body is provided with multiple openings which are configured to expose mask pattern regions of the fine metal mask sheets; the sheet body includes a first region close to a circumferential edge and a second region surrounded by the first region, and a first surface of the second region protrudes from a first surface of the first region in a direction perpendicular to the sheet body; the first surface of the first region is provided with support portions which avoid the openings, and the support portions are configured to support the multiple fine metal mask sheets together with the first surface of the second region.

An embodiment of the disclosure further provides a mask sheet assembly, which includes the full mask sheet, the frame and the multiple fine metal mask sheets; a circumferential edge of the sheet body is provided with lap joints which are lapped and fixed on the frame, two ends of the fine metal mask sheets are fixed on two opposite edgings of the frame, and first sides of the multiple fine metal mask sheets face the first surface of the sheet body.

An embodiment of the disclosure further provides an evaporation device, including an evaporation chamber, an evaporation source disposed in the evaporation chamber, the mask sheet assembly and a magnetic adsorption device; the evaporation source and the magnetic adsorption device are respectively located on upper and lower sides of the mask sheet assembly, the magnetic adsorption device is configured to generate an upward magnetic adsorption force on the full mask sheets, and the fine metal mask sheets are located on a side of the full mask sheet facing the magnetic adsorption device.

Other aspects may be comprehended upon reading and understanding of the drawings and the detailed descriptions.

### BRIEF DESCRIPTION OF DRAWINGS

The attached drawings are for providing a further understanding of technical solutions of the present disclosure and constitute a portion of the description. They are for explaining the technical solutions of the present disclosure together with the embodiments of the present disclosure and do not constitute a limitation on the technical solutions of the present disclosure.

FIG. 1 is a schematic diagram of some mask sheet assemblies being adsorbed by magnetic force in an evaporation chamber in an evaporation process.

FIG. 2 is a schematic diagram of a structure of a frame of a mask sheet assembly in some exemplary embodiments.

FIG. 3a is a schematic diagram of a structure of a phone-type full mask sheet in some exemplary embodiments.

FIG. 3b is a schematic diagram of a structure of a wearable-type full mask sheet in some exemplary embodiments.

FIG. 4 is a schematic diagram of an assembly structure of a mask sheet assembly in some exemplary embodiments.

FIG. 5a is a schematic diagram of a partial structure of a phone-type full mask sheet attached to an FMM in some exemplary embodiments.

FIG. 5b is a schematic diagram of a partial structure of a wearable-type full mask sheet attached to an FMM in some exemplary embodiments;

FIG. 6 is a schematic diagram of a mask sheet assembly in some technologies in an evaporation process;

FIG. 7 is a schematic diagram of a structure of a bulge produced by a FMM in the mask sheet assembly of FIG. 6 in the evaporation process.

FIG. 8 is a schematic diagram of distribution of a region with poor color mixing caused by the base substrate on which a light-emitting layer is evaporated using the mask sheet assembly of FIG. 6.

FIG. 9 is a schematic diagram of a structure of a full mask sheet in some exemplary embodiments.

FIG. 10a is a schematic diagram of positional relation between the full mask sheet of FIG. 9 and two fine metal mask sheets at a portion of the mask sheet assembly in some exemplary embodiments.

FIG. 10b is a schematic diagram of a partial structure at E in FIG. 10a.

FIG. 11 is a schematic diagram of a structure of a full mask sheet in some other exemplary embodiments.

FIG. 12 is a schematic diagram of a structure of an evaporation device in some exemplary embodiments.

### DETAILED DESCRIPTION

Those of ordinary skills in the art should know that modifications or equivalent replacements may be made to the technical solutions of the embodiments of the disclosure without departing from the essence and scope of the technical solutions of the disclosure, and shall all fall within the scope of the claims of the present disclosure.

In the description herein, orientation or positional relations indicated by terms “up”, “down”, “left”, “right”, “top”, “inside”, “outside”, “axial direction”, “four corners” and the like are based on the orientation or positional relations shown in the drawings, and are for an easy and brief description of the present disclosure and are not intended to indicate or imply that the structures referred to must have a specific orientation, or be constructed and operated in a particular orientation, and therefore these expressions should not be construed as limitations on the present disclosure.

In the description herein, the terms “connection”, “fixed connection”, “installation” and “assembly” are to be understood broadly, for example, a connection may be a fixed connection, or a detachable connection, or may be an integral connection, unless explicitly specified and defined otherwise. The terms “installation”, “connection” and “fixed connection” may refer to a direct connection, or may an indirect connection through an intermediate medium, or may be an internal connection between two elements. Those of ordinary skills in the art can understand the meanings of the above terms herein.

In the present disclosure, “parallel” refers to a state in which an angle formed by two straight lines is above −10 degrees and below 10 degrees, and thus also includes a state in which the angle is above −5 degrees and below 5 degrees. In addition, “vertical” refers to a state in which an angle formed by two straight lines is above 80 degrees and below 100 degrees, and thus includes a state in which the angle is above 85 degrees and below 95 degrees.

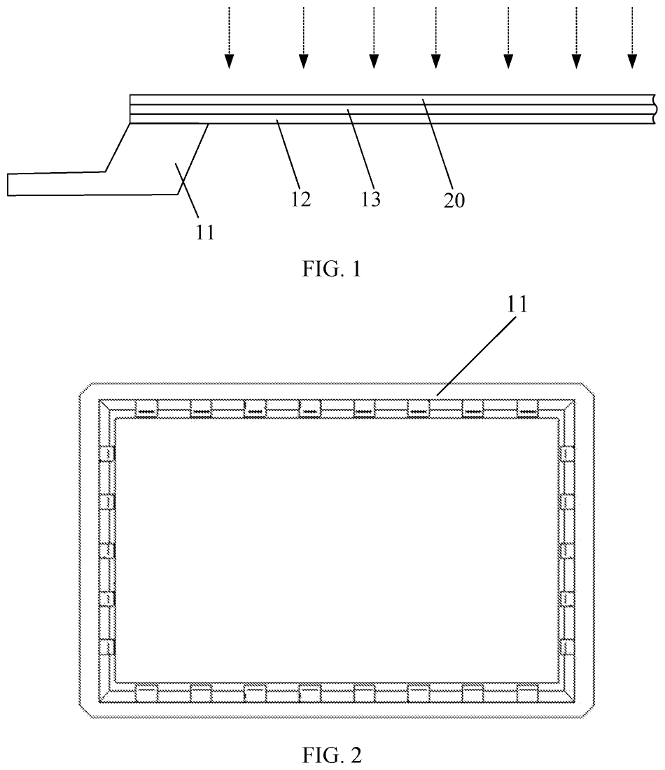

As shown in FIG. 1, FIG. 1 is a schematic diagram of a mask sheet assembly being adsorbed by magnetic force in an evaporation chamber in an evaporation process. The mask sheet assembly is mainly assembled by a frame 11, a full mask sheet 12 and fine metal mask sheets (FMM) 13. The full mask sheet 12 and multiple fine metal mask sheets 13 are all welded on the frame 11, the full mask sheet 12 is mainly used for supporting the fine metal mask sheets 13 and defining an evaporation region of the base substrate 20, and the fine metal mask sheets 13 are supported on the full mask sheet 12. In an evaporation process, the base substrate 20 is placed above the mask sheet assembly, and the full mask sheet 12 of the mask sheet assembly is magnetically adsorbed by a magnetic adsorption device in an evaporation chamber (a straight line with arrow in FIG. 1 indicates magnetic force of the magnetic adsorption device), thereby driving the fine metal mask sheets 13 to be attached to the base substrate 20. Generally, a thickness of a fine metal mask sheet 13 is much smaller than a thickness of the full mask sheet 12, so self-weight and magnetic adsorption strength of the full mask sheet 12 are much greater than those of the fine metal mask sheet 13. Therefore, in the evaporation process, the magnetic force and self-weight of the fine metal mask sheet 13 itself may be ignored, and it may be considered that the fine metal mask sheet 13 is mainly driven by the full mask sheet 12 to be attached to the base substrate 20.

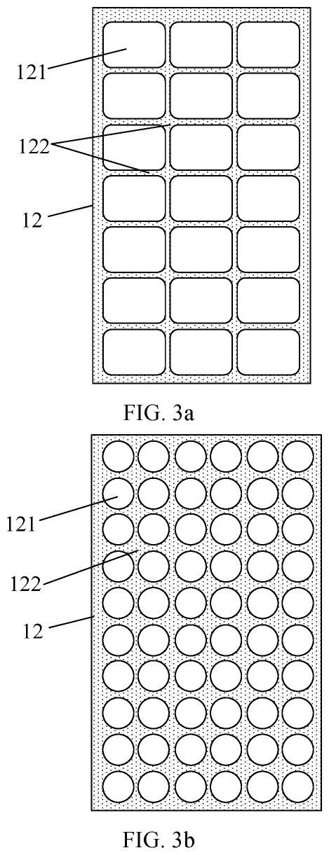

In some exemplary embodiments, FIG. 2 is a schematic diagram of a structure of a frame of a mask sheet assembly. As shown in FIG. 2, the frame 11 may include four edgings, and the frame 11 is in a rectangular frame structure. Four side edges of the full mask sheet 12 are respectively welded to the four edgings of the frame 11 respectively, and the full mask sheet 12 is provided with multiple openings 121 (shown in the examples of FIGS. 3a and 3b), which are respectively used for defining multiple evaporation regions (display regions) of the base substrate 20, and shapes of the openings 121 of the full mask sheet 12 are the same as those of the evaporation regions of the base substrate 20. For example, display regions of phone-type products are generally usually, the openings 121 of the full mask sheet 12 are correspondingly rectangular, and if display regions of some watch-type products are circular, the openings 121 of the full mask sheet 12 are correspondingly circular.

In some exemplary embodiments, FIG. 3a is a schematic diagram of a structure of a phone-type full mask sheet, FIG. 3b is a schematic diagram of a structure of a wearable-type full mask sheet. As shown in FIG. 3a, a full mask sheet 12 with rectangular openings (which may be called a phone-type full mask sheet) may include a support sheet, and the support sheet is provided with multiple rectangular openings 121, wherein the multiple rectangular openings 121 may be arranged in an array, and the number and arrangement of the rectangular openings 121 may be set as required. In other examples, a full mask sheet 12 with rectangular openings may include multiple support bars disposed at intervals along a first direction (which may be a width direction of the full mask sheet 12) and multiple shielding bars disposed at intervals along a second direction (which may be a length direction of the full mask sheet 12). Each shielding bar may extend along the first direction and each support bar may extend along the second direction, and the multiple support bars intersect with the multiple shielding bars to form multiple rectangular openings. As shown in FIG. 3b, a full mask sheet 12 with circular openings (which may be called a wearable-type full mask sheet) may include a support sheet, and the support sheet is provided with multiple circular openings 121, wherein the multiple circular openings 121 may be disposed in an array, and the number and arrangement of the circular openings 121 may be set as required.

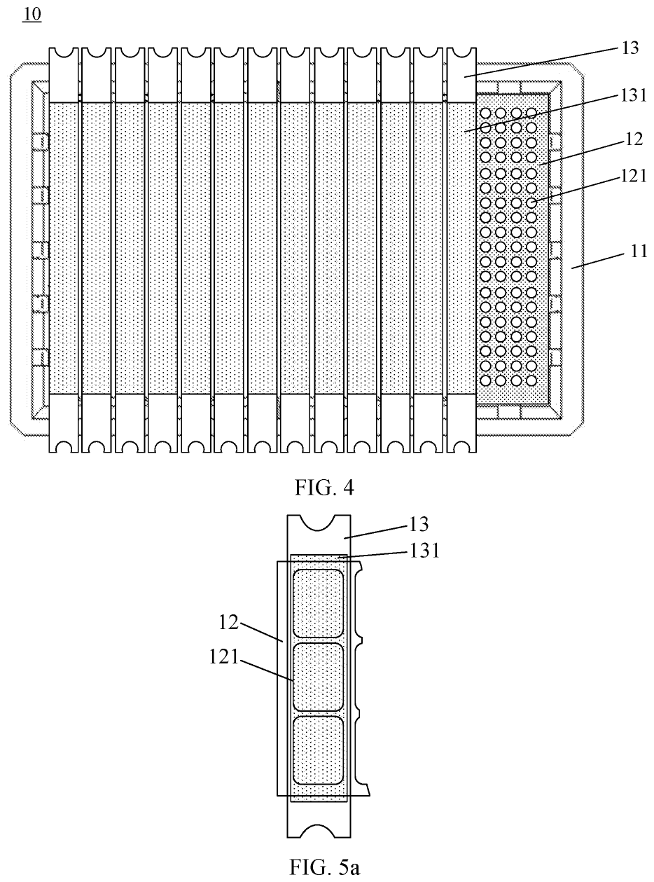

In some exemplary embodiments, as shown in FIG. 4, FIG. 4 is a schematic diagram of an assembly structure of the mask sheet assembly 10, there are two FMMs 13 not shown in FIG. 4, and positions of the FMMs 13 not shown expose a portion of the full mask sheet 12. Four side edges of the full mask sheet 12 are welded to four edgings of the frame 11 respectively. The FMM 13 may have a strip-sheet structure, and the FMM includes a strip-sheet mask sheet body, which is provided with a mask pattern region 131, wherein the mask pattern region 131 may be a whole region. In other examples, the mask sheet body may be provided with multiple mask pattern regions, each of which is exposed by a corresponding opening 121 of the full mask sheet 12. Each FMM 13 may extend along a width direction of the full mask sheet 12, and multiple FMMs 13 are arranged in parallel along a length direction of the full mask sheet 12, and the multiple FMMs 13 are supported on the full mask sheet 12, and two ends of each FMM 13 are respectively welded to two opposite edgings of the frame 11. The number of the openings 121 of the full mask sheet 12 of the mask sheet assembly may be the same as the number of display panels formed in one manufacture procedure. In an assembly process of the mask sheet assembly 10, the full mask sheet 12 may be welded on the frame 11 first, and then the multiple FMMs 13 may be welded on the frame 11 one by one.

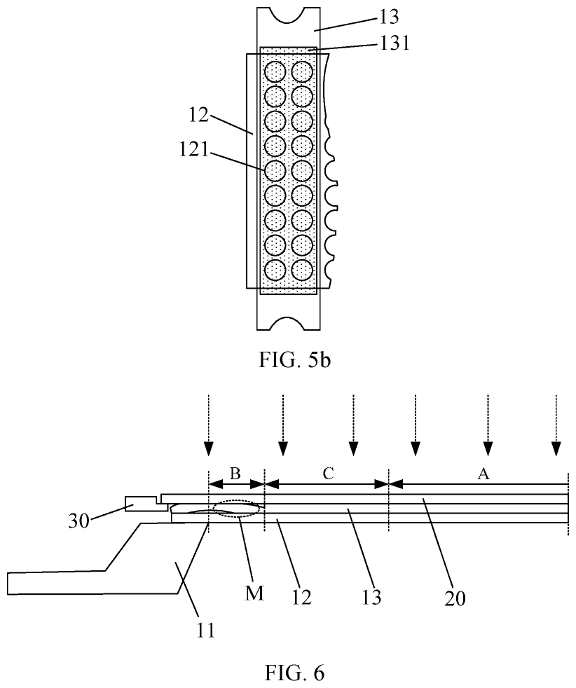

In some exemplary embodiments, FIG. 5a is a schematic diagram of a partial structure of a phone-type full mask sheet attached to an FMM, and FIG. 5b is a schematic diagram of a partial structure of a wearable-type full mask sheet attached to an FMM. As shown in FIG. 5a, the openings 121 of the phone-type full mask sheet 12 are large, and one FMM 13 usually covers one column of openings 121 of the phone-type full mask sheet 12 (the column of openings 121 in FIG. 5a includes three openings 121). As shown in FIG. 5b, the openings 121 of the wearable-type full mask sheet 12 are small, and one FMM 13 usually covers two or more columns of openings 121 (one column of openings 121 in FIG. 5b includes nine openings 121).

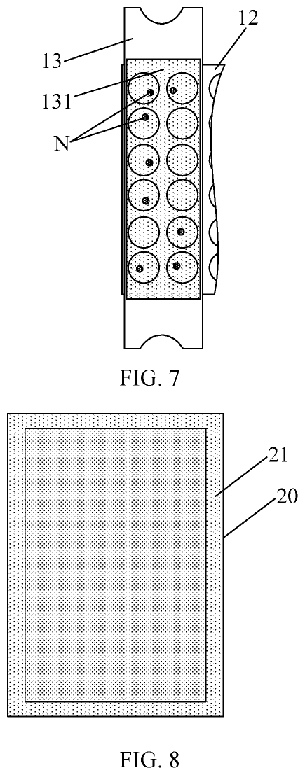

In some exemplary embodiments, as shown in FIG. 6, in a process of forming a light-emitting layer of RGB (red, green and blue) pixels of the base substrate 20 by evaporation, the base substrate 20 is fixed above the mask sheet assembly by a fixing device 30, and the full mask sheet 12 of the mask sheet assembly drives the FMM 13 upward to be attached to the base substrate 20 by magnetic adsorption. In some mask sheet assemblies, a peripheral edge of the full mask sheet 12 is welded and fixed with the frame 11 through a lap joint. The full mask sheet 12 includes a region A in the middle, a region B near the peripheral edge, and a region C located between the region A and the region B. When a light-emitting layer of RGB pixels of a base substrate of a wearable-type product is formed by evaporation, a wearable-type full mask sheet is used as the full mask sheet 12 of the mask sheet assembly. As shown in FIG. 6 and FIG. 7, it is found that in the evaporation process there is a wrinkle M (shown in FIG. 6) in a region of the FMM 13 of the mask sheet assembly corresponding to the region B of the wearable-type full mask sheet 12 and a bulge N (shown in FIG. 7) is formed, leading to a misalignment between the wrinkle region of the FMM 13 and the base substrate 20, worse evaporation accuracy, and causing defects such as color mixing. FIG. 8 shows distribution positions of poor color mixings of some wearable-type product base substrates. It may be seen that the poor color mixings of base substrates 20 of wearable-type products are mainly concentrated in a region 21 near a circumferential edge of the base substrate 20, which corresponds to the region B of the wearable-type full mask sheet 12. When a light-emitting layer of RGB (red, green and blue) pixels of the base substrate 20 of a phone-type product is formed by evaporation, a phone-type full mask sheet is used as the full mask sheet 12 of the mask sheet assembly. In the evaporation process, it is found that there is no above-mentioned problem such as poor color mixing with the base substrates of wearable-type products on the manufactured base substrate of the phone-type product. In addition, there is no phenomenon of wrinkle or bulge in a region of the FMM 13 of the mask sheet assembly corresponding to the region B of the phone-type full mask sheet 12.

When a light-emitting layer of RGB pixels of a base substrate of a wearable-type product is formed by evaporation, FMM produces wrinkles, which leads to poor color mixing of the base substrate of the wearable-type product, while when a light-emitting layer of RGB (red, green and blue) pixels of a base substrate of a phone-type product is formed by evaporation, FMM does not produce wrinkles, and the base substrate of the phone-type product does not produce poor color mixing of the base substrate of the wearable-type product. In view of this phenomenon, the inventor of the present application considers that it is because of differences between structures of the wearable-type full mask sheet and the phone-type full mask sheet.

As shown in FIG. 3a, the openings 121 of the phone-type full mask sheet 12 are rectangular, and as shown in FIG. 3b, the openings 121 of the wearable-type full mask sheet 12 are circular. Compared with the phone-type full mask sheet with rectangular openings, a total area of the opening regions of the wearable-type full mask sheet with circular openings accounts for a smaller proportion. A total area of the opening regions of the full mask sheet with rectangular openings used for manufacturing 7-inch mobile phone products accounts for about 78% of an area of the whole full mask sheet. A total area of the opening regions of the full mask sheet with circular openings used for manufacturing 1.3-inch watch products accounts for about 50% of an area of the whole full mask sheet. Therefore, under a condition that the wearable-type full mask sheet and the phone-type full mask sheet have same sizes, thicknesses and magnetic force, the wearable-type full mask sheet has a larger self-weight, a larger area of an effective region of magnetic adsorption (i.e., a framework region of the full mask sheet) and a stronger magnetic adsorption force than the phone-type full mask sheet.

In addition, as shown in FIG. 5a, the openings 121 of the phone-type full mask sheet 12 are relatively large, and one FMM 13 usually covers one column of openings 121 of the phone-type full mask sheet 12, and an attaching area between the effective region 122 of magnetic adsorption (shown in FIG. 3a) of the phone-type full mask sheet 12 and the FMM 13 is relatively small. A mask pattern region 131 of each FMM 13 is hardly affected by the effective region of magnetic adsorption of the phone-type full mask sheet 12 when the phone-type full mask sheet 12 is magnetically adsorbed in the evaporation chamber, that is, the phone-type full mask sheet 12 hardly restricts flow spread of the FMM 13 in the mask pattern region 131. As shown in FIG. 5b, the openings 121 of the wearable-type full mask sheet 12 are relatively small, and one FMM 13 usually covers two or more columns of openings 121. An attaching area between the effective region 122 of magnetic adsorption (shown in FIG. 3b) of the wearable-type full mask sheet 12 and the FMM 13 is relatively large, and the mask pattern region 131 of each FMM 13 will be affected by the effective region of magnetic adsorption of the wearable-type full mask sheet 12.

As shown in FIG. 6, the region B of the full mask sheet 12 is near a position where the full mask sheet 12 is welded and fixed to the frame 11. In the evaporation process, the region B of the full mask sheet 12 is constrained by the welding fixation and subjected to the action of magnetic adsorption at the same time, while the regions A and C of the full mask sheet 12 are hardly constrained by the welding fixation. In the evaporation process, under the action of magnetic adsorption, in both phone-type mask sheet assembly (a mask sheet assembly using a phone-type full mask sheet) and wearable-type mask sheet assembly (a mask sheet assembly using a wearable-type full mask sheet), regions A and C of the full mask sheet 12 first drive the FMM 13 to be attached to the base substrate 20, and after the regions A and C of the full mask sheet 12 are attached to the FMM 13, the region B of the full mask sheet 12 drives the FMM 13 to be attached to the base substrate 20. Under the action of magnetic adsorption, the regions A and C of the full mask sheet 12 first drive the FMM 13 to be attached to the base substrate 20. Even if the FMM 13 has wrinkles in the regions A and C of the full mask sheet 12, it usually flows and stretches to the region B of the full mask sheet 12 that has not been attached yet. Therefore, the FMM 13 usually is attached well to the base substrate 20 in the regions A and C of the full mask sheet 12 with great evaporation accuracy.

As mentioned above, the mask pattern region of each FMM is less affected by the effective region of magnetic adsorption of the phone-type mask. Even if wrinkles appear in the mask pattern region of the FMM in the region B of the phone-type full mask sheet, the wrinkles are easy to stretch and flow in the mask pattern region of the FMM, so the FMM of the phone-type mask sheet assembly is not easy to produce phenomenon of wrinkles and bulges. As for the wearable-type mask sheet assembly, the mask pattern region of each FMM is greatly influenced by the effective region of magnetic adsorption of the wearable-type full mask sheet. As shown in FIG. 7, after the region B of the wearable-type full mask sheet drives the FMM to be attached to the base substrate, the FMM is fixed between the base substrate and the effective region of magnetic adsorption of the wearable-type full mask sheet. The effective region of magnetic adsorption of the wearable-type full mask sheet will prevent the wrinkles generated in the mask pattern region of the FMM in the region B of the wearable-type full mask sheet from spreading to the periphery to form a bulge, which leads to a misalignment between the wrinkle region of the FMM and the base substrate, and worse evaporation accuracy, and causes defects such as color mixing, etc.

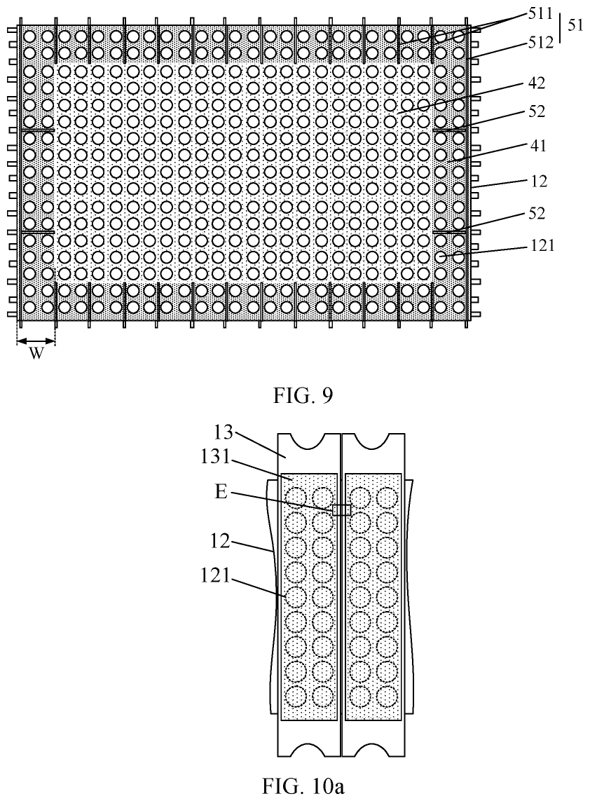

An embodiment of the present disclosure provides a full mask sheet of a mask sheet assembly. In some exemplary embodiments, as shown in FIG. 9, the full mask sheet 12 includes a sheet body including a first surface, wherein the first surface of the sheet body is configured to support multiple fine metal mask sheets 13 of the mask sheet assembly, and the sheet body is provided with multiple openings 121. The openings 121 are configured to expose mask pattern regions 131 of the fine metal mask sheets 13. The sheet body includes a first region 41 near a circumferential edge and a second region 42 surrounded by the first region 41, wherein a first surface of the second region 42 protrudes from a first surface of the first region 41 in a direction perpendicular to the sheet body. The first surface of the first region 41 is provided with support portions which avoid the openings 121, and the support portions are configured to be able to support the multiple fine metal mask sheets 13 together with the first surface of the second region 42.

In the full mask sheet 12 of the mask sheet assembly according to the embodiment of the present disclosure, the first surface of the second region 42 of the full mask sheet 12 protrudes from the first surface of the first region 41, and support portions are disposed on the first surface of the first region 41, wherein the support portions are configured to support multiple fine metal mask sheets 13 of the mask sheet assembly together with the first surface of the second region 42. In this way, in some exemplary embodiments, In an evaporation process of the mask sheet assembly using the full mask sheet 12 of the embodiment of the present disclosure, under the action of magnetic adsorption in the evaporation chamber, the second region 42 of the full mask sheet 12 first drives multiple fine metal mask sheets 13 at the second region 42 to be attached to the base substrate 20, and after the second region 42 of the full mask sheet 12 is attached to the multiple fine metal mask sheets 13 at the second region 42, the first region 41 of the full mask sheet 12 will drive a fine metal mask sheet 13 at the first region 41 (the fine metal mask sheet 13 at the first region 41 may be one or more) to be attached to the base substrate 20. Under the action of magnetic adsorption, the second region 42 of the full mask sheet 12 firstly drives the multiple fine metal mask sheets 13 at the second region 42 to be attached to the base substrate 20, and even if wrinkles appear on the fine metal mask sheets 13 at the second region 42, the wrinkles usually flow and spread to the first region 41 of the full mask sheet 12 which is not attached yet. Therefore, of the multiple fine metal mask sheets 13 at the second region 42 of the full mask sheet 12 generally are not wrinkled, and attached well to the base substrate 20. Accordingly, the evaporation accuracy of the region of the base substrate 20 corresponding to the second region 42 of the full mask sheet 12 is relatively high, and defects such as color mixing are not easy to occur. In a process that the first region 41 of the full mask sheet 12 drives the fine metal mask sheet 13 at the first region 41 to be attached to the base substrate 20, a first side of the fine metal mask sheet 13 at the first region 41 (a first side of the fine metal mask sheet 13 facing a first surface of the sheet body of the full mask sheet 12) is supported on the support portions of the first region 41 and the first surface of the second region 42. Therefore, there is a gap between the first side of the fine metal mask sheet 13 ag the first region 41 and the first surface of the first region 41 of the full mask sheet 12, and the gap can make the fine metal mask sheet 13 at the first region 41 flow and stretch, that is, the first surface of the first region 41 of the full mask sheet 12 will not restrict the wrinkle spreading and flowing in the mask pattern region 131 of the fine metal mask sheet 13 at the first region 41. Therefore, wrinkles of the fine metal mask sheet 13 appearing at the first region 41 may be reduced, so that the fine metal mask sheet 13 may be well attached to the base substrate 20, and position accuracy of the fine metal mask sheet 13 relative to the base substrate 20 may be improved, thereby reducing poor color mixing in the region of the base substrate 20 corresponding to the first region 41 of the full mask sheet 12.

In some exemplary embodiments, as shown in FIG. 9, a thickness of the first region 41 is smaller than that of the second region 42. In an example of this embodiment, a region near the circumferential edge of the first surface of the sheet body of the full mask sheet 12 may be etched and thinned by an etching process, thereby forming the first region 41. To prevent defects such as etching through, a greatest etching depth may be less than ⅓ of a thickness of the whole sheet. In some examples, the thickness of the second region 42 is d, and the thickness of the first region 41 may be more than or equal to 2d/3 and less than d. In a process of forming the first region 41 by the etching thinning process, multiple unetched portions remain in the first region 41, and the multiple unetched portions may be the support portions. The thickness of the first region 41 is smaller than that of the second region 42, so that the first region 41 of the full mask sheet 12 has better flexibility and stretchability than the second region 42, which is more conducive to stretching and flowing of the fine metal mask sheet 13 at the first region 41 and reduces the wrinkles.

In some exemplary embodiments, as shown in FIG. 9, the support portion includes multiple first-direction support portions 51, wherein the first-direction support portions 51 are configured to extend in a first direction. The multiple first-direction support portions 51 include multiple first support portions 511, wherein the first support portions 511 are configured to correspond to boundary positions between two adjacent fine metal mask sheets 13 of the mask sheet assembly, and configured to support one side edge of each fine metal mask sheet 13 of the two adjacent fine metal mask sheets 13. In an example of this embodiment, the first direction is a width direction of the sheet body. In the first region 41, the multiple first support portions 511 are symmetrically disposed with respect to a center line in a length direction of the sheet body. Lengths of the multiple first support portions 511 may be same or different. One end of the multiple first support portions 511 may extend to a boundary between the first region 41 and the second region 42. In a direction perpendicular to the sheet body, the first direction support portions 51 are flush with the first surface of the second region 42, so that the fine metal mask sheets 13 may be uniformly supported.

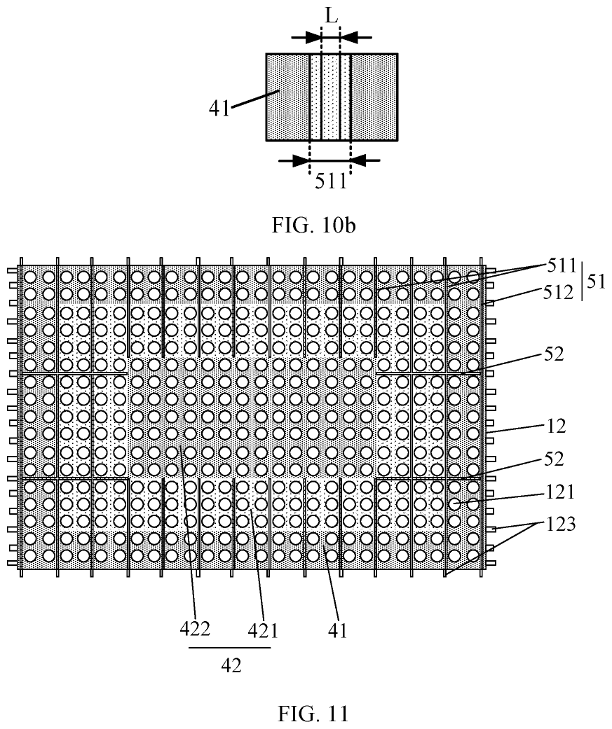

In some exemplary embodiments, as shown in FIG. 9, a width of a first support portion 511 is 0.5 mm to 2 mm. The first support portion 511 has a narrow width and small area, magnetic force applied thereto is very weak, and the blocking and limiting effect on the fine metal mask 13 is also very weak which may be substantially ignored, and will not affect the flowing and stretching of wrinkles of the fine metal mask sheet 13. In an evaporation process, the first support portions 511 may support the fine metal mask sheet 13 together with the first surface of the second region 42 to maintain a more uniform gap between the fine metal mask 13 and the first surface of the first region 41, which is conducive to the flowing and stretching of the wrinkles of the fine metal mask 13. A sectional shape of the first support portion 511 may be rectangular. As shown in FIG. 10a and FIG. 10b, FIG. 10a is a schematic diagram of positional relation between the full mask sheet 12 of FIG. 9 and two fine metal mask sheets 13 of a portion of the mask sheet assembly, As shown in FIG. 10a, the two fine metal mask sheets 13 are supported on a first surface of the sheet body of the full mask sheet 12. The mask pattern regions 131 of the fine metal mask sheets 13 are exposed by multiple openings 121 of the full mask sheet 12. FIG. 10b is a schematic diagram of a partial structure at E in FIG. 10a. It may be seen that a width of the first support portion 511 is larger than a gap width L between two adjacent fine metal mask sheets 13 of the mask sheet assembly, and corresponding two side edges of the two adjacent fine metal mask sheets 13 of the mask sheet assembly are supported on the first support portion 511.

In some exemplary embodiments, as shown in FIG. 9, the multiple first-direction support portions 51 may further include second support portions 512, wherein the second support portions 512 are configured to support a side edge of the fine metal mask 13 at an end of the mask sheet assembly close to the corresponding end of the mask sheet assembly. In an example of this embodiment, as shown in FIG. 9, two second support portions 512 are provided, and the two second support portions 512 are respectively located at two ends of the sheet body in the length direction, wherein one of the second support portions 512 is configured to support one side edge of a fine metal mask sheet 13 close to a first end of the mask sheet assembly, and the other one of the second support portions 512 is configured to support one side edge of the fine metal mask sheet 13 close to a second end of the mask sheet assembly.

In some exemplary embodiments, as shown in FIG. 9, the support portions further include multiple second-direction support portions 52, wherein the second-direction support portions 52 are configured to extend along the second direction, which is perpendicular to the first direction. The multiple second direction support portions 52 are disposed in the first region 41 at two ends of the sheet body in the length direction, and the length direction of the sheet body is parallel to the second direction. The arrangement of the second-direction support portions 52 is can make the full mask sheet 12 bear a large net stretching force, ensuring that a sagging amount of the full mask sheet 12 is within a controllable range. In an example of this embodiment, as shown in FIG. 9, an extension direction of the second-direction support portions 52 may be perpendicular to an extension direction of the first-direction support portions 51. Two adjacent second-direction support portions 52 may be disposed at intervals of multiple openings 121 (in this example, at intervals of six openings 121). One end of the multiple second-direction support portions 52 may extend to a boundary between the first region 41 and the second region 42. In a direction perpendicular to the sheet body, the second-direction support portions 52 are flush with the first surface of the second region 42, so that the second-direction support portions 52 can support the multiple fine metal mask sheets 13 together with the first surface of the second region 42.

In some exemplary embodiments, as shown in FIG. 11, the second region 42 includes a first sub-region 421 close to the first region 41 and a second sub-region 422 surrounded by the first sub-region 421. In the direction perpendicular to the sheet body, a first surface of the second sub-region 422 protrudes from a first surface of the first sub-region 421, and the first surface of the first sub-region 421 protrudes from the first surface of the first region 41. In the direction perpendicular to the sheet body, the first-direction support portions 51 are flush with the first surface of the second sub-region 422. Thus, in some examples, in an evaporation process with a mask sheet assembly using the full mask sheet 12 of this embodiment, under the action of magnetic adsorption in an evaporation chamber, the second sub-region 422, the first sub-region 421 and the first region 41 of the full mask sheet 12 may successively drive the fine metal mask sheets 13 at the corresponding regions to be attached to the base substrate 20, the fine metal mask sheet 13 at the second sub-region 422 will stretch and flow to the first sub-region 421 even if wrinkles occur during an attaching process with the base substrate 20, thus the fine metal mask sheet 14 at the second sub-region 422 is not prone to wrinkles. In a process that the first sub-region 421 and the first region 41 drive the fine metal mask sheets 13 at the corresponding regions to be attached to the base substrate 20, the fine metal mask sheets 13 at the first sub-region 421 and the first region 41 may both be supported on first surfaces of the first-direction support portions 51 and the second sub-region 422. Therefore, There is a gap between a first side of the fine metal mask sheet 13 at the first sub-region 421 and a first surface of the corresponding region of the full mask sheet 12, and the gap may make the fine metal mask sheets 13 at the first sub-region 421 and the first region 41 flow and stretch better and reduce wrinkles, thus reducing the occurrence of poor color mixing in regions of the base substrate 20 corresponding to the first sub-region 421 and the first region 41 of the full mask sheet 12.

In some exemplary embodiments, as shown in FIG. 11, a thickness of the second sub-region 422 is greater than a thickness of the first sub-region 421, and the thickness of the first sub-region 421 is greater than a thickness of the first region 41. In an example of this embodiment, the thickness of the second sub-region 422 is a, the thickness of the first sub-region 421 is b, and the thickness of the first region 41 is c, where a/2≤b<a and b/2≤c<b. In an example of this embodiment, a first surface of the full mask sheet 12 may be thinned and etched by regions by thinning and etching, so as to form a second sub-region 422, a first sub-region 421 and a first region 41 of the sheet body of the full mask sheet 12, and thicknesses of the second sub-region 422, the first sub-region 421 and the first region 41 and a protruding height of the first surface are all different. The thicknesses of the second sub-region 422, the first sub-region 421 and the first region 41 decreases in turn, so that the magnetic adsorption effects acted on the second sub-region 422, the first sub-region 421 and the first region 41 also decreases in turn. Compared with the second sub-region 422, the first sub-region 421 and the first region 41 can slowly drive the fine metal mask sheets 13 at the corresponding regions to be attached to the base substrate 20, which is conducive to the slow stretching of the fine metal masks 13 at the first sub-region 421 and the first region 41, thereby reducing occurrence of wrinkles.

In some exemplary embodiments, as shown in FIG. 11, support portions of the first region 41 may extend into the first sub-region 421, for example, multiple first support portions 511 of multiple first-direction support portions 51 of the first region 41 may extend into the first sub-region 421 and may extend to a boundary between the first sub-region 421 and the second sub-region 422. In addition, in the direction perpendicular to the sheet body, the first-direction support portions 51 are flush with the first surface of the second sub-region 422. In this way, the first-direction support portions 51 and the first surface of the second sub-region 422 may support the fine metal mask sheets 13 more uniformly, and a gap between a first side of the fine metal mask sheet 13 at the first sub-region 421 and the first region 41 and a first surface of the corresponding region of the full mask sheet 12 may be made more uniformly during the evaporation process, which is conducive to reducing occurrence of wrinkles in the first sub-region 421 and the first region 41.

In some exemplary embodiments, as shown in FIG. 11, multiple second-direction support portions 52 of the first region 41 may extend into the first sub-region 421 and may extend to a boundary between the first sub-region 421 and the second sub-region 422. In an example of this embodiment, in the direction perpendicular to the sheet body, the second-direction support portions 52 are flush with the first surface of the second sub-region 422. In this way, in the evaporation process, the second-direction support portions 52 may support the fine metal mask sheet 13 in the corresponding region, and the full mask sheet 12 may support the fine metal mask sheet 13 more uniformly, so that a more uniform gap is kept between the first surface of the full mask sheet 12 and the fine metal mask sheet 13, which is beneficial to reducing occurrence of wrinkles of the fine metal mask sheet 13.

In some exemplary embodiments, as shown in FIG. 9, a width W of the first region 41 along the length direction of the sheet body is equal to a width of one or more fine metal mask sheets 13, wherein the length direction of the sheet body may be perpendicular to an extension direction of the first-direction support portions 51, which may be parallel to a length direction of the fine metal mask sheets 13. In the example of FIG. 9, it may be considered that the width W of the first region 41 along the length direction of the sheet body is equal to a width of one fine metal mask sheet 13, and one fine metal mask sheet 13 may cover two columns of openings 121.

In some exemplary embodiments, as shown in FIG. 9, a shape of the opening 121 may be circular, a shape of outline of the sheet body of the full mask sheet 12 may be rectangular, and multiple openings 121 may be arranged in an array with multiple rows and multiple columns. The second region 42 is rectangular, and a circumferential edge of the first region 41 may extend to four side edges of the sheet body of the full mask sheet 12. In other examples, a shape of the openings 121 may be oval, polygonal or irregular.

In some exemplary embodiments, as shown in FIG. 11, the circumferential edge of the sheet body of the full mask sheet 12 may be provided with lap joints 123, which are configured to be lapped and fixed on the frame 11 of the mask sheet assembly. In an example of this embodiment, four side edges of the sheet body of the full mask sheet 12 are provided with multiple protrusions protruding toward outside of the sheet body and the multiple protrusions are the lap joints 123. Multiple protrusions on the four side edges of the sheet body may be lapped and welded on the four edgings of the frame 11.

An embodiment of the present disclosure further provides a mask sheet assembly, which includes the full mask sheet 12, the frame 11 and multiple fine metal mask sheets 13 as described in any of the foregoing embodiments. In some examples, as shown in FIG. 4, lap joints 123 (shown in FIG. 11) are disposed at a circumferential edge of the sheet body of the full mask sheet 12, and the lap joints 123 are lapped and fixed on the frame 11. Two ends of each fine metal mask sheet 13 are fixed on two opposite edgings of the frame 11, and first sides of the multiple fine metal mask sheets 13 face the first surface of the sheet body. The length direction of the fine metal mask sheets 13 may be parallel to the width direction of the full mask sheet 12.

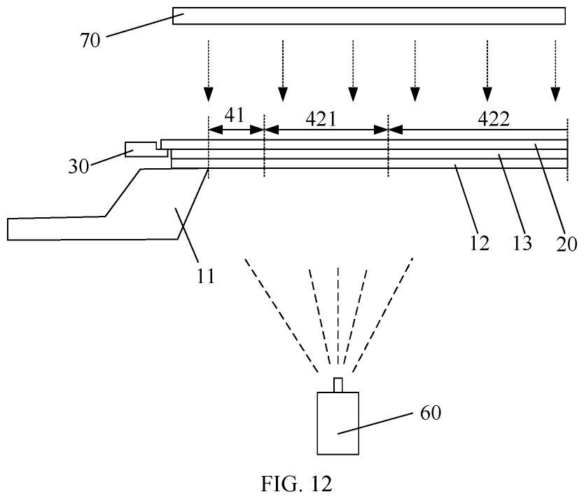

An embodiment of the present disclosure further provide an evaporation device, in some examples, as shown in FIG. 12, the evaporation device includes an evaporation chamber, an evaporation source 60 disposed in the evaporation chamber, a mask sheet assembly described in any of the foregoing embodiments and a magnetic adsorption device 70. The evaporation source 60 and the magnetic adsorption device 70 are located on upper and lower sides of the mask sheet assembly respectively. The magnetic adsorption device 70 is configured to generate an upward magnetic adsorption force on the full mask sheet 12, and the fine metal mask sheet 13 is located on a side of the full mask sheet 12 facing the magnetic adsorption device 70.

In an evaporation process, under the action of the magnetic adsorption of the magnetic adsorption device 70, the full mask sheet 12 may drive the fine metal mask sheet 13 upward to be attached to the base substrate 20. An evaporation material in the evaporation source 60 is heated to form vapor, which passes through openings 121 of the full mask sheet 12 and is deposited in a preset region of the base substrate 20 through the mask pattern region 131 of the fine metal mask sheet 13, thereby a film layer with a corresponding pattern on the base substrate 20 is formed and a defect of color mixing at an edge region of the base substrate 20 is reduced.

What is claimed is:

1. A full mask sheet of a mask sheet assembly, comprising a sheet body which comprises a first surface, wherein the first surface of the sheet body is configured to support a plurality of fine metal mask sheets of the mask sheet assembly, and the sheet body is provided with a plurality of openings which are configured to expose mask pattern regions of the fine metal mask sheets;
the sheet body comprises a first region close to a circumferential edge and a second region surrounded by the first region, and a first surface of the second region protrudes from a first surface of the first region in a direction perpendicular to the sheet body; and
support portions are disposed on the first surface of the first region, wherein the support portions avoid the openings, and is configured to support the plurality of fine metal mask sheets together with the first surface of the second region.

2. The full mask sheet of the mask sheet assembly according to claim 1, wherein the support portions comprise a plurality of first-direction support portions, and the first-direction support portions are configured to extend along a first direction;
the plurality of first-direction support portions comprise a plurality of first support portions, and the first support portions are configured to correspond to a boundary position between two adjacent fine metal mask sheets of the mask sheet assembly, and are configured to support one side edge of each fine metal mask sheet of the two adjacent fine metal mask sheets.

3. The full mask sheet of the mask sheet assembly according to claim 2, wherein a width of a first support portion is 0.5 mm to 2 mm.

4. The full mask sheet of the mask sheet assembly according to claim 2, wherein the plurality of first-direction support portions further comprise second support portions, and the second support portions are configured to support a side edge of the fine metal mask sheet located at an end of the mask sheet assembly close to a corresponding end of the mask sheet assembly.

5. The full mask sheet of the mask sheet assembly according to claim 2, wherein the support portions further comprise a plurality of second-direction support portions, and the second-direction support portions are configured to extend along a second direction, and the second direction is perpendicular to the first direction; and
the plurality of second direction support portions are disposed in regions of the first region located at two ends in a length direction of the sheet body, and the length direction of the sheet body is parallel to the second direction.

6. The full mask sheet of the mask sheet assembly according to claim 2, wherein one end of the plurality of first support portions extends to a boundary between the first region and the second region.

7. The full mask sheet of the mask sheet assembly according to claim 2, wherein the first-direction support portions are flush with the first surface of the second region in the direction perpendicular to the sheet body.

8. The full mask sheet of the mask sheet assembly according to claim 5, wherein the second-direction support portions are flush with the first surface of the second region in the direction perpendicular to the sheet body.

9. The full mask sheet of the mask sheet assembly according to claim 1, wherein a thickness of the first region is smaller than a thickness of the second region.

10. The full mask sheet of the mask sheet assembly according to claim 2, wherein the second region comprises a first sub-region close to the first region and a second sub-region surrounded by the first sub-region;
in the direction perpendicular to the sheet body, a first surface of the second sub-region protrudes from a first surface of the first sub-region, which protrudes from the first surface of the first region; and
in the direction perpendicular to the sheet body, the first-direction support portions are flush with the first surface of the second sub-region.

11. The full mask sheet of the mask sheet assembly according to claim 10, wherein a plurality of the first-direction support portions extend into the first sub-region.

12. The full mask sheet of the mask sheet assembly according to claim 10, wherein the support portions further comprise a plurality of second-direction support portions, and the second-direction support portions are configured to extend along a second direction, and the second direction is perpendicular to the first direction;
the plurality of second-direction support portions are disposed in regions of the first region located at to ends in a length direction of the sheet body, and extend into the first sub-region, and the length direction of the sheet body is parallel to the second direction.

13. The full mask sheet of the mask sheet assembly according to claim 12, wherein the second-direction support portion are flush with the first surface of the second sub-region in the direction perpendicular to the sheet body.

14. The full mask sheet of the mask sheet assembly according to claim 10, wherein a thickness of the second sub-region is greater than a thickness of the first sub-region and the thickness of the first sub-region is greater than a thickness of the first region.

15. The full mask sheet of the mask sheet assembly according to claim 2, wherein a width of the first region along a length direction of the sheet body is equal to a width of one or more of the fine metal mask sheets and the length direction of the sheet body is perpendicular to the first direction.

16. The full mask sheet of the mask sheet assembly according to claim 1, wherein a shape of the openings is circular, oval, polygonal or irregular.

17. A mask sheet assembly comprising the full mask sheet according to claim 1, a frame and multiple fine metal mask sheets;
the circumferential edge of the sheet body is provided with lap joints which are lapped and fixed on the frame, two ends of the fine metal mask sheets are fixed on two opposite edgings of the frame, and first sides of the multiple fine metal mask sheets face the first surface of the sheet body.

18. An evaporation device, comprising an evaporation chamber, an evaporation source disposed in the evaporation chamber, the mask sheet assembly according to claim 17 and a magnetic adsorption device;
the evaporation source and the magnetic adsorption device are respectively located on upper and lower sides of the mask sheet assembly, the magnetic adsorption device is configured to generate an upward magnetic adsorption force on the full mask sheets, and the fine metal mask sheets are located on a side of the full mask sheet facing the magnetic adsorption device.

19. The full mask sheet of the mask sheet assembly according to claim 3, wherein the second region comprises a first sub-region close to the first region and a second sub-region surrounded by the first sub-region;
in the direction perpendicular to the sheet body, a first surface of the second sub-region protrudes from a first surface of the first sub-region, which protrudes from the first surface of the first region; and
in the direction perpendicular to the sheet body, the first-direction support portions are flush with the first surface of the second sub-region.

20. The full mask sheet of the mask sheet assembly according to claim 4, wherein the second region comprises a first sub-region close to the first region and a second sub-region surrounded by the first sub-region;
in the direction perpendicular to the sheet body, a first surface of the second sub-region protrudes from a first surface of the first sub-region, which protrudes from the first surface of the first region; and
in the direction perpendicular to the sheet body, the first-direction support portions are flush with the first surface of the second sub-region.
